(19) United States
(12) Patent Application Publication
(10) Pub. No.: US 2016/0027743 A1
(43) Pub. Date: Jan. 28, 2016

(54) SEMICONDUCTOR DEVICE

(71) Applicant: Kazuyuki KAKISAKI, Chuo-ku, Tokyo (JP)

(72) Inventor: Kazuyuki Kakisaki, Tokyo (JP)

(21) Appl. No.: 14/771,798

(22) PCT Filed: Mar. 3, 2014
(86) PCT No.: PCT/JP2014/055304

§ 371 Date: Aug. 31, 2015

(30) Foreign Application Priority Data
Mar. 5, 2013 (JP) 2013-042574

(51) Int. Cl. H01L 23/00; H01L 27/108

(52) U.S. Cl. CPC H01L 23/562; H01L 27/10814

(57) ABSTRACT

One semiconductor device includes, in a memory mat, a plurality of memory cells having a plurality of capacitors including cylindrical lower electrodes. The semiconductor device includes a first support film pattern group having a plurality of polygonal support film patterns as seen in plan view within the memory mat, wherein each supports sidewalls of corresponding lower electrodes, and a second support film pattern group having a plurality of polygonal support film patterns as seen in plan view within the memory mat, wherein each supports sidewalls of corresponding lower electrodes. The second support film pattern group is formed above the first support film pattern group so that periphery vertices of the respective polygons, as seen in plan view, do not overlap with each other.

### INDUSTRIAL FIELD

The present invention relates to a semiconductor device.

### BACKGROUND

With developments in miniaturization of semiconductor devices, the area of a memory cell constituting a dynamic random access memory (DRAM) element has shrunk. Therefore, capacitors are usually formed in a three-dimensional shape to ensure that the capacitors constituting a memory cell have sufficient electrostatic capacity. Specifically, the surface area may be increased by making the lower electrodes of the capacitors cylindrical to use both the inner and outer sidewalls of the lower electrodes as capacitors.

With shrinkage of the area of a memory cell, however, the area of the floors of the lower electrodes of the capacitors has also shrunk, and a phenomenon (called collapse) of the lower electrodes collapsing and shorting the lower electrodes tends to occur during a production process for exposing the outer sidewalls of capacitors using cylindrical lower electrodes (wet etching of a capacitor interlayer sacrificial film; called crown wet etching or the like).

Patent Document 1 has proposed a technique of arranging a support film pattern for supporting between adjacent lower electrodes to prevent collapse of the lower electrodes. More particularly, as shown in FIG. 2 of Patent Document 1, a support film pattern fastening the upper ends between lower electrodes can apparently disperse the stress brought to bear during wet etching of a capacitor interlayer sacrificial film. A support film pattern such as shown in FIG. 13 of Patent Document 1 forms a structure having a firmer support film pattern as a synthetic pattern of a line/space (L/S) pattern running in both X- and Y-directions.

### PATENT DOCUMENT

### Patent Document 1: Japanese Unexamined Patent Publication No. 2010-147078 (FIGS. 2 and 13)

### OUTLINE OF THE INVENTION

### Problems that the Invention is to Solve

The present inventors discovered a new problem, however, when a support film pattern such as disclosed by Patent Document 1 was used. This problem will be described with reference to FIG. 1. On the right side, FIG. 1 shows a support film pattern 300 in a memory mat in plan view omitting the cylindrical lower electrodes. Blank areas in this plan view indicate windows (slits) formed in a grid in the support film pattern 300. On the left side, FIG. 1 shows a magnified sectional structure of the portion within the circle on the right side of FIG. 1; that is, cylindrical lower electrodes 350 and the support film pattern 300 supporting the upper ends of these electrodes. A force such as shown by the blank arrows on the right side of FIG. 1 acts on the support film pattern 300 of this memory mat. The arrows on the right side of FIG. 1 indicate the direction and size of displacement. That is, a greater displacement toward the center acts on the support film pattern 300 closer to the edges.

As a result, during a wet etching process for removing a capacitor interlayer sacrificial film (not shown) buried between adjacent lower electrodes 350, a phenomenon has been confirmed in which the cylindrical lower electrodes 350 arranged near the edges of the memory mat slope greatly toward the inside of the memory mat, as shown on the left side of FIG. 1. In locations where the degree of the slope is bad, places were confirmed where shorting between cylindrical lower electrodes 350 occurred due to the influence of the slope (caused by a slight difference in bending, where the bending was due to a slight difference in cylinder diameter). If shorting occurs between lower electrodes 350, a countermeasure to sloping of the lower electrodes 350 is required.

The direct cause of sloping of the lower electrodes 350 is compression applied horizontally to the support film pattern 300 fabricated of a nitride film material. The present inventors think that the support film pattern 300 is not acted upon by a compressive force when in a state having a capacitor interlayer sacrificial film adhered, but is subject to a compressive force from the instant that adhesion is released by wet etching of the capacitor interlayer sacrificial film. The lower electrodes 350 slope more at the edges of the memory mat because the compressive force acts toward the center of the memory mat, and the edges of the memory mat are the areas of greatest displacement due to this compression.

As a countermeasure to this sloping of the lower electrodes 350 at the edges of a memory mat, the present inventors studied splitting up the support film pattern 300 into a honeycomb shape of polygons, such as hexagons, of a size which fits into a region of several micrometers square. FIG. 2 shows a plan view of an example of such a honeycomb. Splitting up the support film pattern in a memory mat in FIG. 2 into a honeycomb shape by separation films (shown by solid lines in FIG. 2) forming hexagons was found to improve sloping of the lower electrodes at the edges of the memory mat. Hereafter, the pattern formed by splitting into polygons such as hexagons will be called the support film pattern SPT. The many diagonal lines formed in a grid in each support film pattern SPT in FIG. 2 indicate windows (slits) like the windows shown on the right side of FIG. 1. Needless to say, no slits are formed near the separation lines.

The present inventors discovered a new problem, however, when a support film pattern in a memory mat was split up into a honeycomb shape. FIG. 3 shows the nature of this problem. As shown in FIG. 3(a), when a support film pattern in a memory mat is split up into a honeycomb shape, the lower electrodes LE located at the three separation overlap points in the regions divided into three sides at the portions corresponding to the vertices of the hexagonal support film pattern SPT (hereafter called separation overlap points) are only supported at about one third the entire perimeter of the lower electrode.

After many fabrication attempts, the present inventors discovered the following. When the gap between two adjacent support film patterns—that is, the separation width (the width of the separation lines)—was made somewhat larger (FIG. 3(b)), or when an overlap misalignment (misalignment relative to the cylinder pattern) occurred in the support film pattern SPT (FIG. 3(c)), the lower electrodes LE located at the separation overlap points were supported even less by the support film pattern SPT (little contact area), and the lower electrodes LE had a high risk of coming off from the support film pattern SPT. FIG. 3(b) shows that when the separation lines of the hexagonal support film pattern SPT are larger, the lower electrodes, such as the lower electrodes within the thick solid-line circles, are not supported by the support film pattern SPT over most of the perimeter (no contact). FIG. 3(c) shows that when an overlap misalignment in the direction of the arrow occurs in a support film pattern SPT, the lower electrodes within the thick solid-line circles are not supported by the support film pattern SPT over most of the perimeter. When the overlap misalignment is opposite to the direction of the arrow, the lower electrodes within the dashed-line circles are not supported by the support film pattern SPT over most of the perimeter.

According to results of trial manufacture by the present inventors, when the supported length of the perimeter of the lower electrodes LE is less than one third, there is a fairly high probability that the lower electrodes LE will fall off the support film pattern SPT during wet etching of the capacitor sacrificial interlayer film (described later).

Therefore, a problem addressed by the present invention is to provide a semiconductor device in which the support film pattern can be split up without the lower electrodes coming off from the support film pattern.

### Means of Solving the Problems

Besides a configuration for supporting lower electrodes by a split-up support film pattern above the lower electrodes, another split-up support film pattern is formed near midway up the lower electrodes, and the lower electrodes are supported by the two upper and lower split-up support film patterns. In this case, the separation overlap points of the upper and lower support film patterns do not overlap (do not match) in plan view. Specifically, as shown in FIG. 4, both the upper and lower patterns are split up into honeycomb-shaped (hexagonal) support film patterns (residual patterns) SPT-2 and SPT-1 by an outline pattern comprising a repeating pattern, but the layout of one support film pattern is slightly offset from the other support film pattern in any direction so that the separation overlap points do not overlap as seen in plan view. As a result, a lower electrode (not shown) located at a separation overlap point of one support film pattern is not located at a separation overlap point of the other support film pattern. Therefore, even if the lower electrode (not shown) at the separation overlap point is supported by a support film pattern for less than one third the length of the perimeter, support by the other support film pattern is not limited to less than one third the length of the perimeter, thus avoiding the risk of the lower electrode coming off from both the upper and lower support film patterns (not being supported by either). FIG. 4(a) is a plan view of the memory mat and FIG. 4(b) is a sectional view at line A-A′ of FIG. 4(a), where FIG. 4(b) is drawn exaggerated for better understanding, and is not drawn so as to correspond to FIG. 4(a). Although the two upper and lower support film patterns SPT-2 and SPT-1 are split up in the same shape in FIG. 4(a), the shape need not be the same.

According to results of trial manufacture by the present inventors, although some effect could be confirmed even when the separation overlap points of two upper and lower support film patterns overlapped in plan view, the present inventors concluded that to securely prevent a lower electrode coming off from support by the support film patterns, the separation overlap points of the two upper and lower support film patterns should be offset so that one or the other of the two upper and lower support film patterns supports half or more of the perimeter of the lower electrode.

Based on such findings, one aspect of the present invention provides a semiconductor device in which a plurality of memory cells are provided in a memory mat; each of the plurality of memory cells has a plurality of capacitors; each of the capacitors has a cylindrical lower electrode; a first support film pattern group is provided comprising a plurality of polygonal support film patterns within the memory mat as seen in plan view, each supporting a sidewall of the corresponding lower electrode; a second support film pattern group is provided comprising a plurality of polygonal support film patterns within the memory mat as seen in plan view, each supporting a sidewall of the corresponding lower electrode; and the second support film pattern group is formed above the first support film pattern group so that the peripheral vertices of the polygons do not overlap each other as seen in plan view.

Another aspect of the present invention provides a semiconductor device in which a plurality of memory cells are provided in a memory mat; each of the plurality of memory cells has a plurality of capacitors; each of the capacitors has a cylindrical lower electrode; a first support film pattern group is provided having an outline pattern comprising a repeating pattern within the memory mat, and comprising a support film pattern supporting the corresponding lower electrode at a sidewall; a second support film pattern group is provided having an outline pattern of the same repeating pattern as the first support film pattern group within the memory mat, and comprising a support film pattern located above the first support film pattern group while supporting the corresponding lower electrode at a sidewall; and the outline pattern comprising the repeating pattern of the first support film pattern group does not match the outline pattern comprising the repeating pattern of the second support film pattern group as seen in plan view, and each outline pattern is an outline pattern extending in two or more directions while turning.

Another aspect of the present invention provides a semiconductor device in which a plurality of memory cells are provided in a memory mat; each of the plurality of memory cells has a plurality of capacitors; each of the capacitors has a cylindrical lower electrode; a first support film pattern group is provided divided by separation lines within the memory mat and supporting the sidewalls of the lower electrodes; a second support film pattern group is provided divided by separation lines within the memory mat, located above the first support film pattern group, and supporting the sidewalls of the lower electrodes; and the lower electrodes are divided into a first group located at a separation overlap point where the separation lines of the first support film pattern group come together, supported at less than half of the perimeter of the sidewall by one support film pattern of the first support pattern group, and supported at half or more of the perimeter of the sidewall by one support film pattern of the second support pattern group; a second group located at a separation overlap point where the separation lines of the second support film pattern group come together, supported at half or more of the perimeter of the sidewall by one support film pattern of the first support pattern group, and supported at less than half of the perimeter of the sidewall by one support film pattern of the second support pattern group; and a third group supported at half or more of the perimeter of the sidewall by one support film pattern of the first support pattern group, and supported at half or more of the perimeter of the sidewall by one support film pattern of the second support pattern group.

### Effects of the Invention

Instead of only taking a countermeasure to sloping at the edges of a memory map, the present invention is designed so that one or the other of two upper and lower support film patterns always supports each lower electrode at half or more of the perimeter of the sidewall. This eliminates the trouble of a lower electrode coming off from support by a support film pattern or a lower electrode which has come off shorting with another lower electrode, and leads to improved product quality.

### BRIEF EXPLANATION OF THE DRAWINGS

FIG. 1 is a schematic diagram illustrating sloping of the lower electrodes of capacitors constituting a memory cell;

FIG. 2 is a plan view showing a portion of a memory mat illustrating means provided by the present inventors for a countermeasure to prevent the sloping of the lower electrodes shown in FIG. 1;

FIG. 3 is a magnified plan view showing a portion of a memory mat illustrating several examples of the problems of the means of FIG. 2;

FIG. 4 is a plan view (FIG. 4(a)) and a sectional view (FIG. 4(b)) showing a portion of a memory mat illustrating the principles of the present invention;

FIG. 5 is a block diagram showing the schematic configuration of a DRAM as an example of a semiconductor device to which the present invention has been applied;

FIG. 6 is a plan view illustrating an example of the internal configuration of a DRAM chip;

FIG. 7 is a conceptual diagram showing the planar configuration of a memory cell portion of a DRAM element pertaining to the semiconductor device of an embodiment of the present invention;

FIG. 8 is a schematic sectional view corresponding to line A-A′ in FIG. 7;

FIG. 9 is a schematic sectional view illustrating a process in a method of producing the semiconductor device of an embodiment of the present invention;

FIG. 10 is a schematic sectional view illustrating the process following FIG. 9 in a method of producing the semiconductor device of an embodiment of the present invention;

FIG. 11 is a schematic sectional view illustrating the process following FIG. 10 in a method of producing the semiconductor device of an embodiment of the present invention;

FIG. 12 is a schematic sectional view illustrating the process following FIG. 11 in a method of producing the semiconductor device of an embodiment of the present invention;

FIG. 13 is a schematic sectional view illustrating the process following FIG. 12 in a method of producing the semiconductor device of an embodiment of the present invention;

FIG. 14 is a schematic sectional view illustrating the process following FIG. 13 in a method of producing the semiconductor device of an embodiment of the present invention;

FIG. 15 is a schematic sectional view illustrating the process following FIG. 14 in a method of producing the semiconductor device of an embodiment of the present invention;

FIG. 16 is a schematic sectional view illustrating the process following FIG. 15 in a method of producing the semiconductor device of an embodiment of the present invention;

FIG. 17 is a schematic sectional view illustrating the process following FIG. 16 in a method of producing the semiconductor device of an embodiment of the present invention;

FIG. 18A is a plan view showing Example 1 of how to offset the first and second support film patterns in the semiconductor device of an embodiment of the present invention;

FIG. 18B is a sectional view at line B-B′ in FIG. 18A;

FIG. 19 is a plan view of Example 2 of how the first and second support film patterns are offset in the semiconductor device of an embodiment of the present invention;

FIG. 20 is a plan view of Example 3 of how the first and second support film patterns are offset in the semiconductor device of an embodiment of the present invention;

FIG. 21 is a plan view of Example 4 of how the first and second support film patterns are offset in the semiconductor device of an embodiment of the present invention; and

FIG. 22 is a plan view of Example 5 of how the first and second support film patterns are offset in the semiconductor device of an embodiment of the present invention.

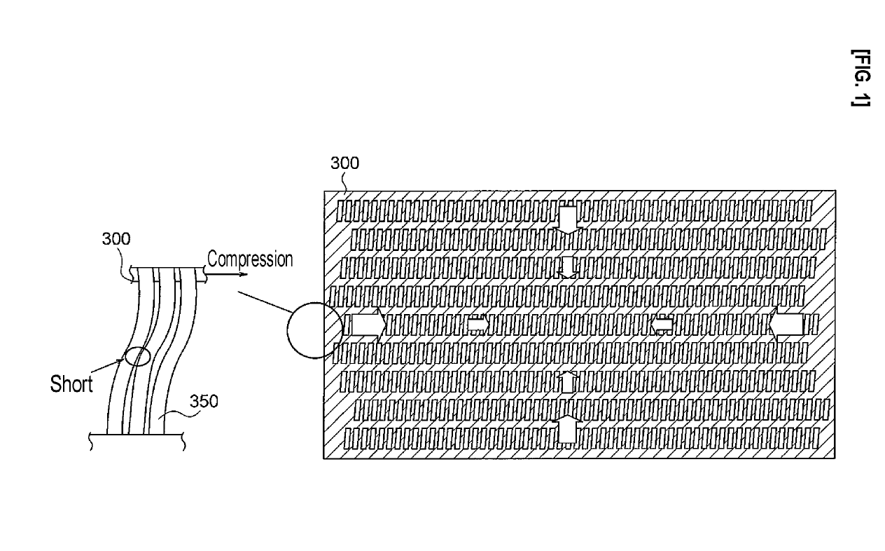

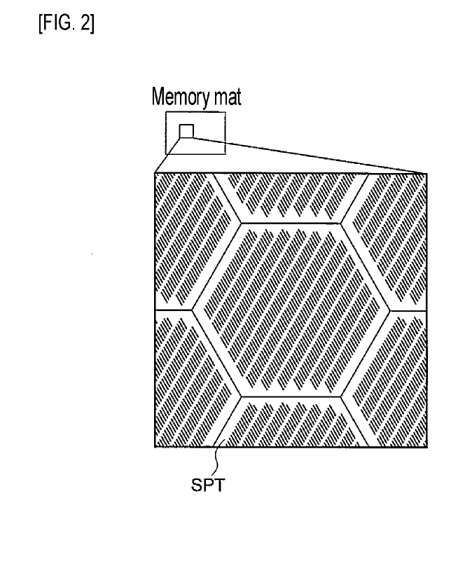

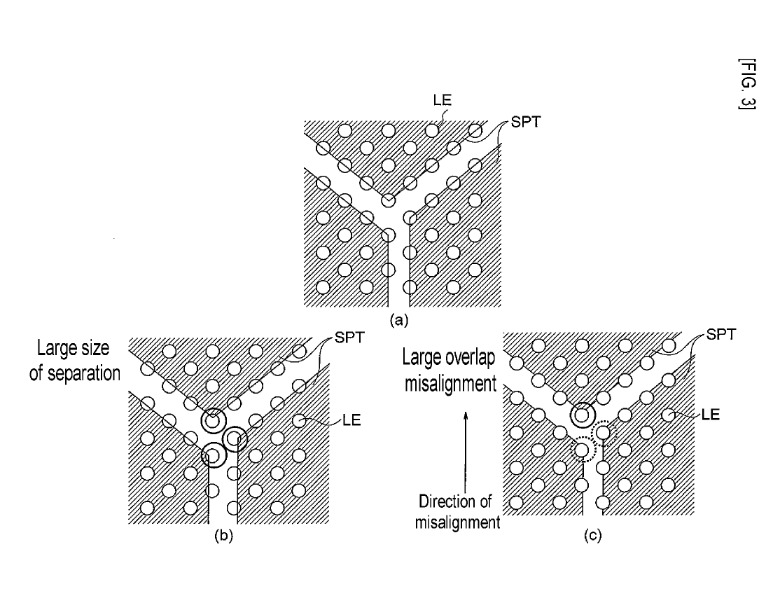

### EMBODIMENTS OF THE INVENTION

Embodiments of the present invention will be described in detail hereinafter with reference to the annexed drawings.

An example of a semiconductor device to which the present invention may be applied is a DRAM. The present invention, however, is not limited to a DRAM, and may be applied to various types of semiconductor devices.

An outline configuration of a DRAM 100 will be described with reference to FIG. 5. The DRAM 100 includes a plurality of memory cell arrays 101, and a peripheral circuit capable of accessing or refreshing these memory cell arrays 101.

The peripheral circuit includes an internal clock generating circuit 102, a command decoder 103, a control circuit 104, a mode register 105, a low address buffer and refresh counter 106, a column address buffer and burst counter 107, a low decoder 108, a column decoder 109, a sense amplifier group 110, a data control circuit 111, a latch circuit 112, a data (DQ) input/output circuit 113, and a delay locked loop (DLL) 114.

The operation of the DRAM 100 is not related to the essence of the present invention, and will not be described here.

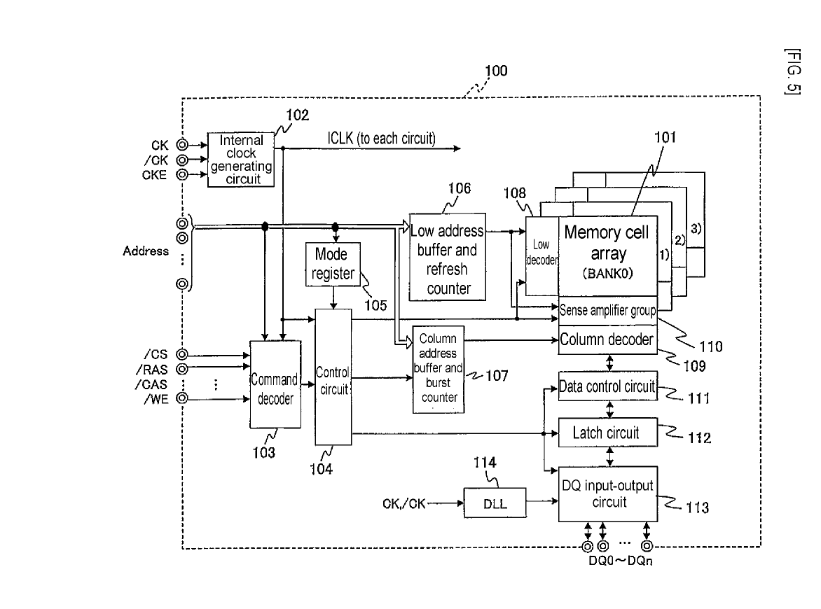

Each of the plurality of memory cell arrays 101 comprises a plurality of subarrays. The plurality of subarrays are disposed in a memory cell array region (memory mat) 201 arrayed on a semiconductor substrate 200 as shown in FIG. 6.

Returning to FIG. 5, the sense amplifier group 110 is divided into subgroups corresponding to the subarrays. A plurality of sense amplifiers contained in each subgroup are disposed in a sense amplifier (SA) portion 202 (located above and below in FIG. 6) adjacent to each memory cell array region 201.

The low decoder 108 is hierarchized, and includes a plurality of sub-word drivers. The plurality of sub-word drivers are disposed in a sub-word driver (SWD) portion 203 (located to the left and right in FIG. 6) adjacent to each memory cell array region 201.

The region excluding the memory cell array regions 201, the SA portions 202, the SWD portions 203, and the intersecting portions 204 where the SA portions 202 intersect the SWD portions 203 is used as a peripheral circuit region 205 where the remainder of the peripheral circuit is disposed.

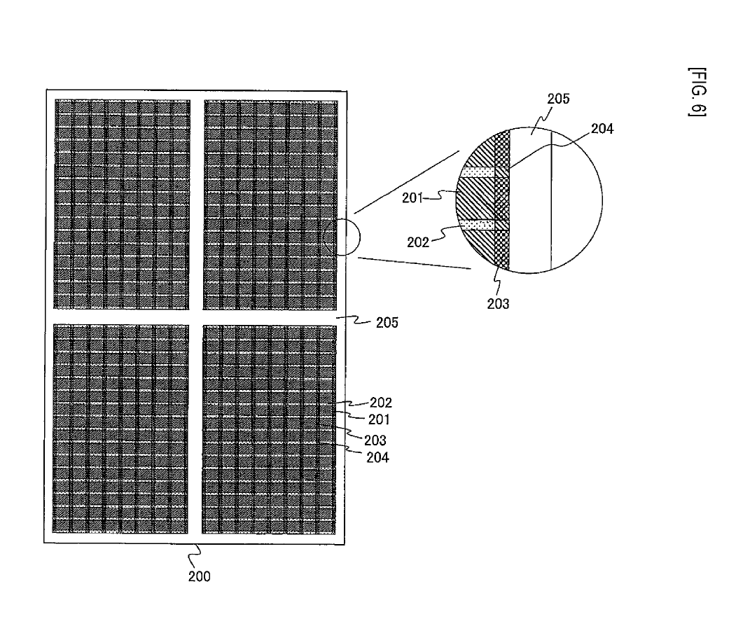

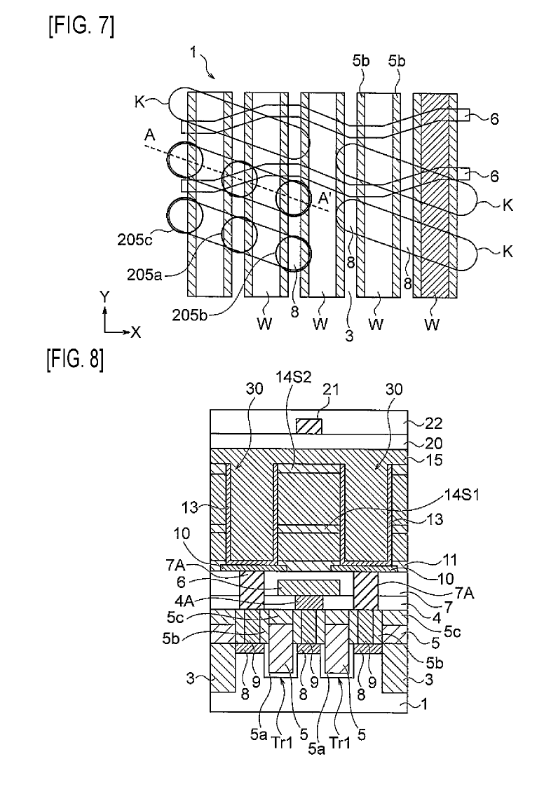

Next, the memory cell portion of a DRAM element will be described as an embodiment of the semiconductor device according to the present invention with reference to FIGS. 7-8.

FIG. 7 is a conceptual diagram showing the planar configuration of the memory cell portion of the DRAM element, and shows only some of the elements constituting the memory cell. FIG. 8 is a schematic sectional view corresponding to line A-A′ in FIG. 7. These drawings illustrate the configuration of the semiconductor device, but the size or dimensions of the various components shown differ from the dimensional relationships of an actual semiconductor device.

As shown in FIG. 8, the memory cell portion roughly comprises a MOS transistor Tr1 for a memory cell, and a capacitor element (capacitor) 30 connected to the MOS transistor Tr1 through a plurality of contact plugs.

In FIGS. 7-8, the semiconductor substrate 1 is formed by silicon (Si) containing a predetermined concentration of a P-type impurity. An element separation region 3 is formed in the semiconductor substrate 1. The element separation region 3 is partially formed, except for an active region K, by burying an insulating film such as a silicon dioxide (SiO₂) film in the surface of the semiconductor substrate 1 by shallow trench isolation (STI), which separates and insulates between adjacent active regions. The present embodiment shows an example of the present invention applied to a configuration in which two bits of memory cell are arranged in one active region K.

In the present embodiment, a plurality of long and narrow rectangular active regions K are arranged in an array slanting downward to the right with a predetermined spacing in between, as in the planar configuration shown in FIG. 7. Impurity diffusion layers are formed in the center and both ends of each active regions K, and function as the source and drain regions of the MOS transistor Tr1. Substrate contact portions 205a, 205b, and 205c are positioned so as to be arranged just above the source and drain regions (impurity diffusion layers).

Although an array of active regions K such as in FIG. 7 is a shape peculiar to the present embodiment, the shape of the active regions K and the direction of the array is not specifically limited. The active regions K shown in FIG. 7 may be made other active region shapes conventionally applied to a transistor.

A bit wiring 6 extends in a polygonal line (curve) in the horizontal (X) direction in FIG. 7, and a plurality of these bit wirings 6 are arranged at a predetermined spacing in the vertical (Y) direction of FIG. 7. A linear word wiring W is arranged extending in the vertical (Y) direction of FIG. 7, and is configured so as to include gate electrodes 5 shown in FIG. 8 in the portions where the word wiring W intersects the active regions K. In the present embodiment, a MOS transistor Tr1 is shown as an example provided with groove-shaped gate electrodes. A planar-type transistor, or a MOS transistor having a channel region formed in a side portion of a channel disposed in the semiconductor substrate, may be used instead of a MOS transistor provided with groove-shaped electrodes.

As shown by the sectional configuration in FIG. 8, isolated impurity diffusion layers 8 functioning as source and drain regions are formed in the semiconductor substrate 1 divided by the element separation regions 3, and groove-shaped gate electrodes 5 are formed between the impurity diffusion layers 8. The gate electrode 5 is formed of a multilayer film of a polycrystalline silicon film and a metal film so as to protrude above the semiconductor substrate 1. The polycrystalline silicon film may be formed containing an impurity such as phosphorus during film formation by chemical vapor deposition (CVD). A polycrystalline silicon film formed without containing an impurity during film formation may be doped with an N-type or P-type impurity by ion injection in a later process. A high melting point metal and a compound thereof, such as tungsten (W) and tungsten nitride (WN) or tungsten silicide (WSi), may be used in the metal film used for the gate electrode.

As shown in FIG. 8, a gate insulating film 5a is formed between the gate electrode 5 and the semiconductor substrate 1. A sidewall 5b is formed on the sidewall of the gate electrode 5 by an insulating film such as silicon nitride (Si₃N₄). A cap insulating film 5c such as silicon nitride is also formed above the gate electrode 5.

The impurity diffusion layer 8 is formed by doping the semiconductor substrate 1 with phosphorus, for example, as an N-type impurity. A substrate contact plug 9 is formed so as to contact the impurity diffusion layer 8. Substrate contact plugs 9 are arranged in the locations of substrate contact portions 205c, 205a, and 205b shown in FIG. 7, and formed, for example, of a polycrystalline silicon containing phosphorus. The width of the substrate contact plug 9 in the horizontal (X) direction is self-aligned by the sidewall 5b disposed on the adjacent gate wiring W.

As shown in FIG. 8, a first interlayer insulating film 4 is formed so as to cover the substrate contact plug 9 and the cap insulating film 5c on the gate electrode 5, and a bit-line contact plug 4A is formed so as to pass through the first interlayer insulating film 4. The bit-line contact plug 4A is arranged in the location of the substrate contact portion 205a, and is conductive with the substrate contact plug 9. The bit-line contact plug 4A is formed by laminating tungsten (W) or the like onto a barrier film (TiN/Ti) comprising a laminate film of titanium (Ti) and titanium nitride (TiN). The bit wiring 6 is formed so as to connect with the bit-line contact plug 4A. The bit wiring 6 is formed of a laminate film comprising tungsten nitride (WN) and tungsten (W).

A second interlayer insulating film 7 is formed so as to cover the bit wiring 6. A capacitor contact plug 7A connected to the substrate contact plug 9 is formed passing through the first interlayer insulating film 4 and the second interlayer insulating film 7. Capacitor contact plugs 7A are arranged in the locations of the substrate contact portions 205b and 205c.

A capacitor contact pad 10 is formed and arranged on the second interlayer insulating film 7, and is conductive with the capacitor contact plug 7A. The capacitor contact pad 10 is formed of a laminate film comprising tungsten nitride (WN) and tungsten (W). A third interlayer insulating film 11 using silicon nitride is formed so as to cover the capacitor contact pad 10.

A capacitor element 30 is formed passing through the third interlayer insulating film 11 so as to connect to the capacitor contact pad 10.

The capacitor element 30 comprises a capacitor insulating film (not shown) between the lower electrode 13 and the upper electrode 15, and the lower electrode 13 is conductive with the capacitor contact pad 10. Two upper and lower support portions are formed by first and second support film patterns 14S1 and 14S2, which are formed so as to contact the sides of the lower electrode 13 both at an intermediate portion and at the upper end in the height direction. As a result, the lower electrode 13 is supported so as not to come off from support by the support film pattern during the course of the production process (wet etching of a capacitor interlayer sacrificial film; described later).

A capacitor element for storage is not arranged in regions (such as the peripheral circuit region) other than the memory cell region of the DRAM element, and a fourth interlayer insulating film (not shown), formed of silicon nitride or the like, is formed on the third interlayer insulating film 11.

A fifth interlayer insulating film 20, an upper wiring layer formed of aluminum (Al), copper (Cu), or the like, and a surface protective film 22 are formed on the capacitor element 30 in the memory cell portion.

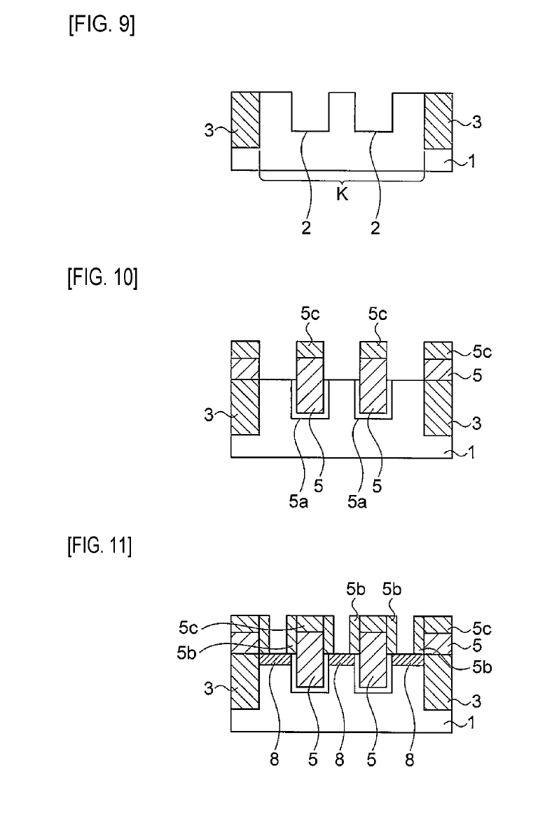

Next, the method for producing the semiconductor device of the present embodiment will be described with reference to FIGS. 9-17. FIGS. 9-17 are schematic sectional views corresponding to line A-A′ in the memory cell portion (FIG. 7).

As shown in FIG. 9, an element separation region 3 having a buried insulating film such as silicon oxide (SiO₂) is formed by STI in portions other than an active region K in order to mark off the active region K on the principal surface of a semiconductor substrate 1 comprising a P-type silicon.

Next, a gate electrode groove pattern 2 for a MOS transistor Tr1 is formed. The groove pattern 2 is formed by etching the silicon of the semiconductor substrate 1 using a pattern (not shown) formed by a photoresist.

Next, a gate insulating film 5a having a thickness of about 4 nm is formed by thermal oxidation in a transistor formation region by oxidizing the silicon surface of the semiconductor substrate 1 to silicon oxide. A laminate film of silicon oxide and silicon nitride, or a high dielectric film (high-K film) may be used as the gate insulating film.

Subsequently, a polycrystalline silicon film containing phosphorus (P) as an N-type impurity is deposited on the gate insulating film 5a by CVD using monosilane (SiH₄) and phosphine (PH₃) as raw material gases. The thickness of the film deposited during this deposition is set so as to completely fill inside the gate electrode groove pattern 2 with the polycrystalline silicon film. A polycrystalline silicon film not containing an impurity such as phosphorus may be formed, and the polycrystalline silicon film may be doped with a desired impurity by ion injection in a later process. Next, a high melting point metal such as tungsten, tungsten nitride, or tungsten silicide is deposited as a metal film by sputtering to a thickness of about 50 nm on the polycrystalline silicon film. The polycrystalline film and the metal film will form the gate electrode 5 through a process described later.

Next, a cap insulating film 5c comprising silicon nitride is deposited to a thickness of about 70 nm on the metal film that will constitute the gate electrode 5 by plasma CVD using monosilane and ammonia (NH₃) as raw material gases. Next, a photoresist pattern for forming the gate electrode 5 is formed on the cap insulating film 5c by photolithography using a mask for forming the gate electrode 5.

The cap insulating film 5c is then etched by aleotropic etching using the photoresist pattern as a mask. Next, after the photoresist pattern has been removed, the metal film and the polycrystalline silicon film are etched using the cap insulating film 5c as a hard mask to form the gate electrode 5. The gate electrode 5 will function as a word line W (FIG. 7).

Next, as shown in FIG. 11, phosphorus ions are injected as an N-type impurity to form impurity diffusion layers 8 on the active region K where not covered by the gate electrode 5. Subsequently, a silicon nitride film is deposited by CVD to a thickness of about 20-50 nm over the entire surface, then etched to form a sidewall 5b on the sidewall of the gate electrode 5.

Next, after an interlayer insulating film (not shown) such as silicon oxide is formed by CVD so as to cover the cap insulating film 5c and the sidewall 5b on the gate electrode, and the surface is polished by chemical mechanical polishing (CMP) to smooth any irregularities caused by the gate electrode 5. Polishing of the surface is stopped at the point when the upper surface of the cap insulating film 5c on the gate electrode is exposed.

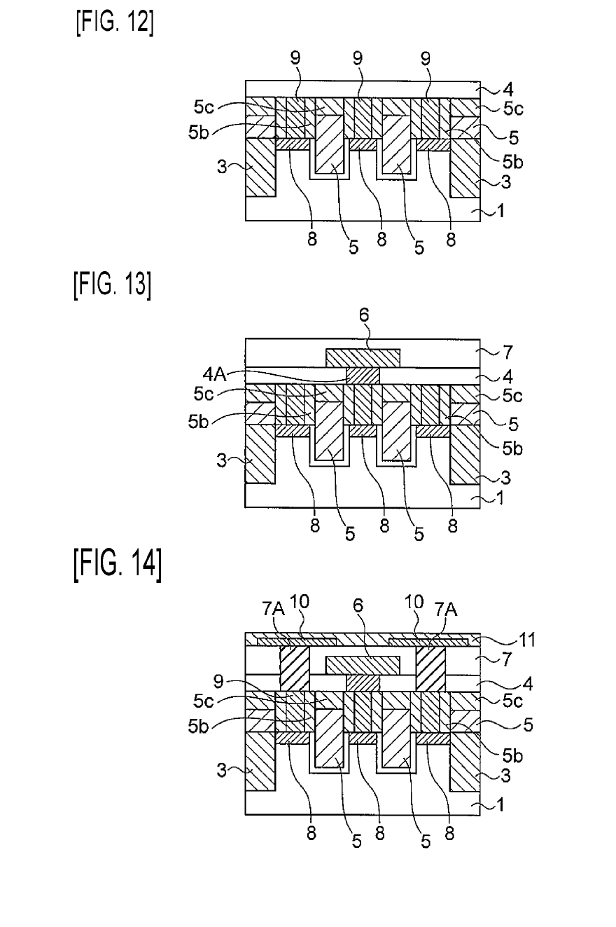

Subsequently, the substrate contact plug 9 is formed as shown in FIG. 12. Specifically, first, etching is performed using a pattern formed by a photoresist as a mask so as to form openings in the locations of the substrate contact portions 205a, 205b, and 205c in FIG. 7. The openings may be disposed between the gate electrodes 5 by self-alignment using the cap insulating film 5c and the sidewall 5b formed of silicon nitride. Subsequently, after a polysilicon film containing phosphorus is deposited by CVD, the surface is polished by CMP to remove the polycrystalline silicon film on the gate electrode 5 and form the substrate contact plug 9 filling inside the opening.

Subsequently, the first interlayer insulating film 4 comprising silicon oxide is formed by CVD to a thickness of about 600 nm, for example, so as to cover the substrate contact plug 9 and the cap insulating film 5c on the gate electrode. Subsequently, the surface of the first interlayer insulating film 4 is polished by CMP to a thickness of about 300 nm, for example, and smoothed.

Next, as shown in FIG. 13, an opening (contact hole) in the location of the substrate contact portion 205a in FIG. 7 is formed in the first interlayer insulating film 4, and the surface of the substrate contact plug 9 is exposed. A film of tungsten (W) laminated onto a barrier film such as TiN/Ti is deposited so as to fill inside this opening, and the surface is polished by CMP to form the bit-line contact plug 4A. Subsequently, the bit wiring 6 is formed so as to connect with the bit-line contact plug 4A. Next, the second interlayer insulating film 7 is formed of silicon oxide or the like so as to cover the bit wiring 6.

Next, as shown in FIG. 14, openings (contact holes) are formed so as to pass through the first interlayer insulating film 4 and the second interlayer insulating film 7 in the locations of the substrate contact portions 205b and 205c in FIG. 7, and the surface of the substrate contact plug 9 is exposed. A film of tungsten (W) laminated onto a barrier film such as TiN/Ti is deposited so as to fill inside the opening, and the surface is polished by CMP to form the capacitor contact plug 7A.

The capacitor contact pad 10 is formed on the second interlayer insulating film 7 using a laminated film containing tungsten. The capacitor contact pad 10 is conductive with the capacitor contact plug 7A, and is arranged at a size which is greater than the size of the floor of the lower electrode of the capacitor element to be formed later. Subsequently, the third interlayer insulating film 11 is deposited using silicon nitride or the like at a thickness of 60 nm, for example, so as to cover the capacitor contact pad 10.

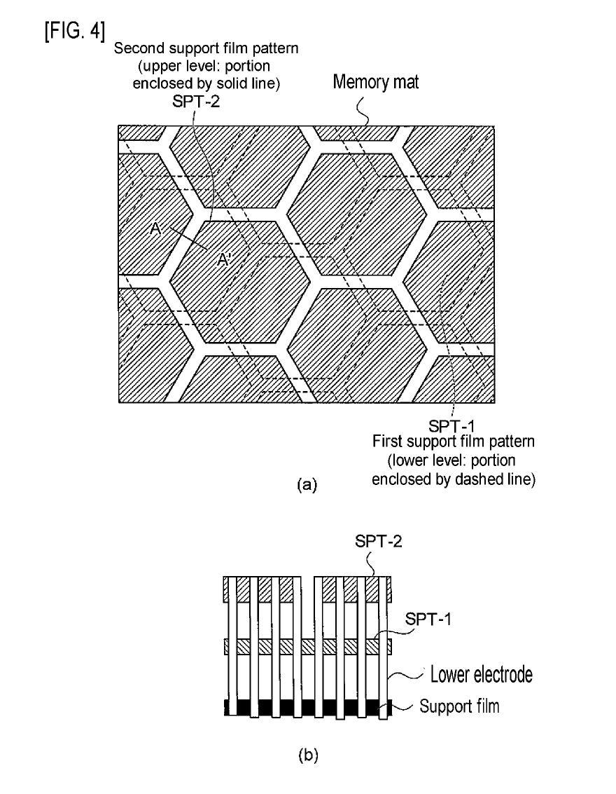

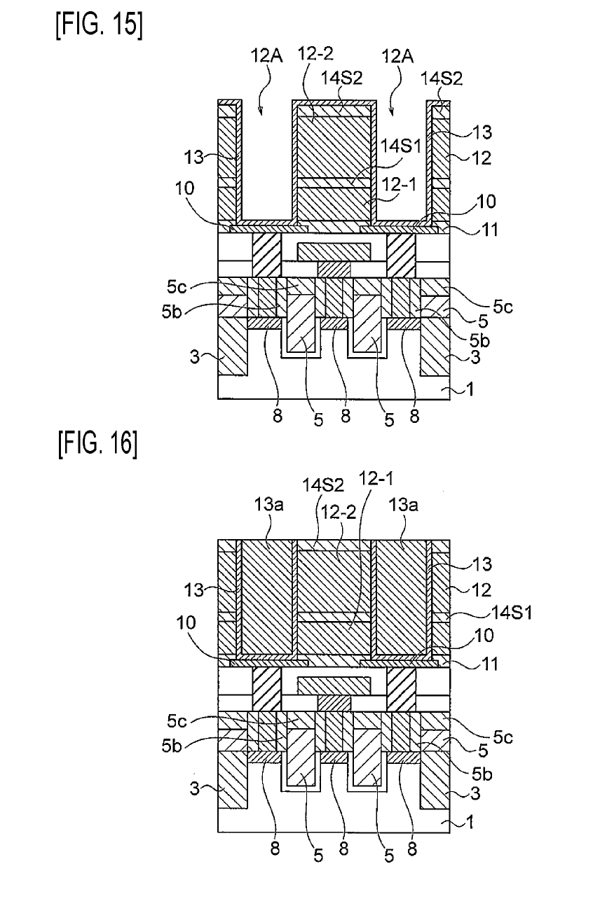

Next, as shown in FIG. 15, after a plasma oxide film is deposited at a thickness of 1 μm, for example, as a first sacrificial interlayer film (sacrificial oxide film) 12-1, a silicon nitride film is deposited at a thickness of 40 nm, for example, as a first support film. Next, a plurality of first support film patterns SPT-1 split up in a honeycomb shape of polygons (hexagons) such as described using FIG. 4(a) and a plurality of first support film patterns 14S1 are formed as a first support film pattern group using means such as photolithography and dry etching. After the resist is removed and a plasma oxide film is deposited at a thickness of 1 μm, for example, as a second sacrificial interlayer film (sacrificial oxide film) 12-2, a silicon nitride film is formed at a thickness of 40 nm, for example, as a second support film. The first and second sacrificial interlayer films (sacrificial oxide films) 12-1 and 12-2 may be jointly called the fourth interlayer insulating film.

Subsequently, openings (capacitor holes) 12A are formed by aleotropic etching in the location where a capacitor element will be formed, and the surface of the capacitor contact pad 10 is exposed. After the openings 12A are formed, the lower electrodes 13 of the capacitor element are formed. Specifically, titanium nitride is deposited at a film thickness which does not completely fill the inside of the openings 12A. A metal film other than titanium nitride may be used as the material of the lower electrodes.

Next, as shown in FIG. 16, the titanium nitride 13 on the second support film is removed by dry etching or CMP. During this removal, the inside of the opening 12A is filled with a protective film 13a such as silicon oxide to protect the lower electrode inside the opening 12A. Subsequently, the second support film is patterned by aleotropic dry etching, and a plurality of second support film patterns SPT-2 split up in a honeycomb shape of polygons (hexagons) such as described using FIG. 4(a) and a plurality of second support film patterns 14S2 are formed as a second support film pattern group by aleotropic dry etching.

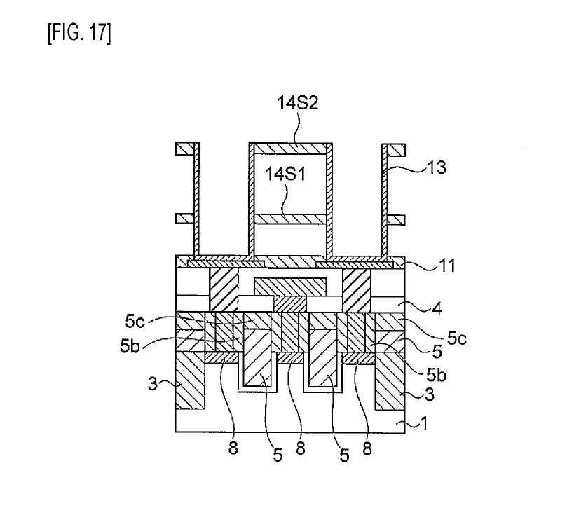

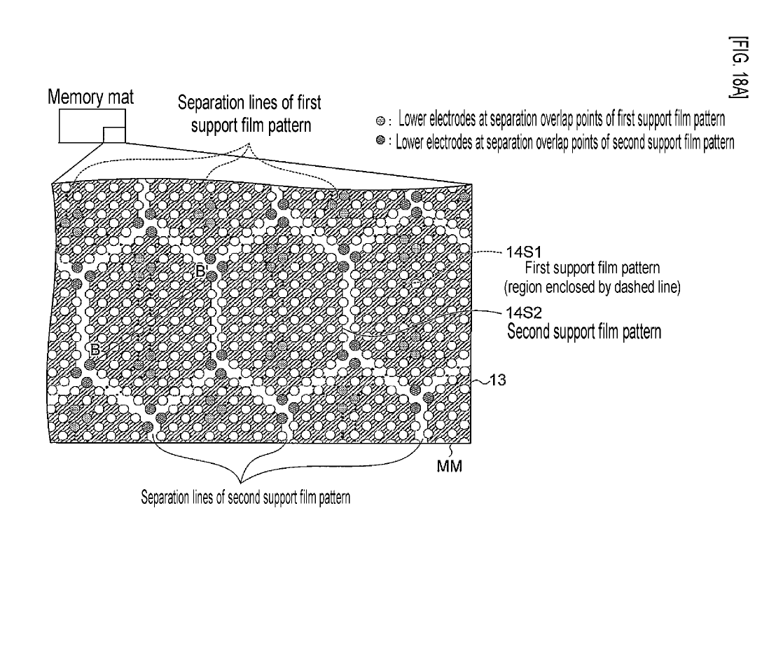

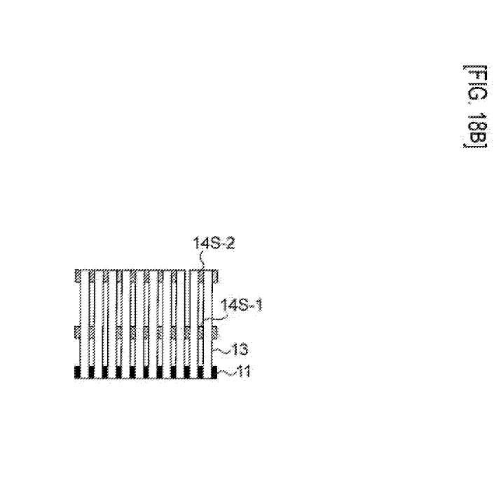

Next, as shown in FIG. 17, the first and second sacrificial interlayer films 12-1 and 12-2 and the protective film 13a are removed in the memory cell portion by wet etching using hydrofluoric acid (HF) to expose the inside and outside walls of the lower electrodes 13. The third interlayer insulating film 11 formed of silicon nitride functions as a stopper film (FIG. 4(b)) during this wet etching to prevent etching of elements or the like located in lower layers. The third interlayer insulating film 11 also has a function supporting the sidewall located below the lower electrodes 13. The third interlayer insulating film 11 in regions other than the memory cell portion can also prevent infiltration of chemicals during wet etching.

If a material such as a SOG film which is wet-etched at a sufficiently faster, such as about five times faster, etching speed than a silicon oxide film is used as the protective film 13a, the protective film 13a is preferably removed completely when the first and second sacrificial interlayer films 12-1 and 12-2 are removed.

Next, a capacitor insulating film (not shown) is formed so as to cover the surface of the sidewalls of the lower electrodes 13. A high dielectric film such as hafnium oxide (HfO₂), zirconium oxide (ZrO₂), aluminum oxide (Al₂O₃), or a laminate of these may be used as the capacitor insulating film.

Next, as shown in FIG. 8, the upper electrodes 15 of the capacitor element are formed of titanium nitride or the like. The capacitor element 30 is formed by holding the lower electrodes 13 and the upper electrodes 15 between capacitor insulating films (not shown).

Subsequently, the fifth interlayer insulating film 20 is formed of silicon oxide or the like. A drawing contact plug (not shown) for applying an electric potential to the upper electrodes 15 of the capacitor element is formed in the memory cell portion.

Subsequently, an upper wiring layer 21 is formed of aluminum (Al), copper (Cu), or the like. The surface protective film 22 is then formed of silicon oxynitride (SiON) or the like to complete the memory cell portion of the DRAM element.

Various examples of how the first support film pattern 14S1 described using FIG. 15 is offset from the second support film pattern 14S2 described using FIG. 16 may be considered according to the design of the (outline) pattern of separation lines comprising the repeating pattern by which the support film patterns are separated into residual patterns. Several preferred examples will be described hereinafter as examples.

### Example 1

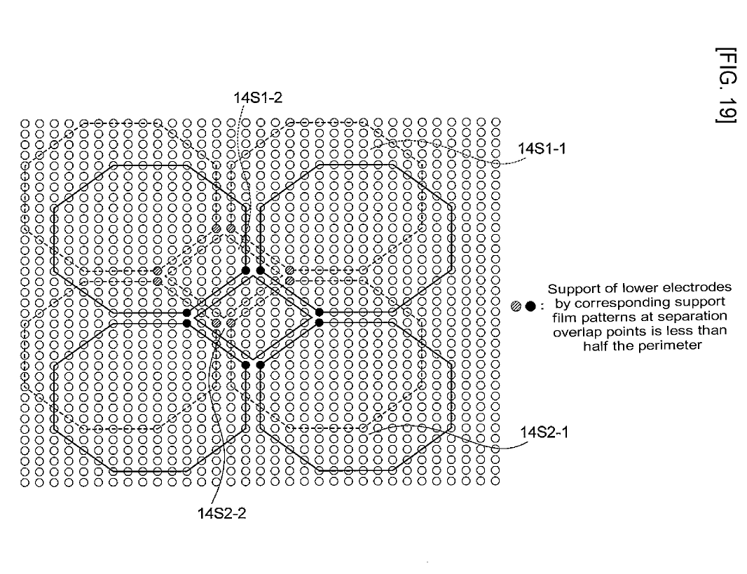

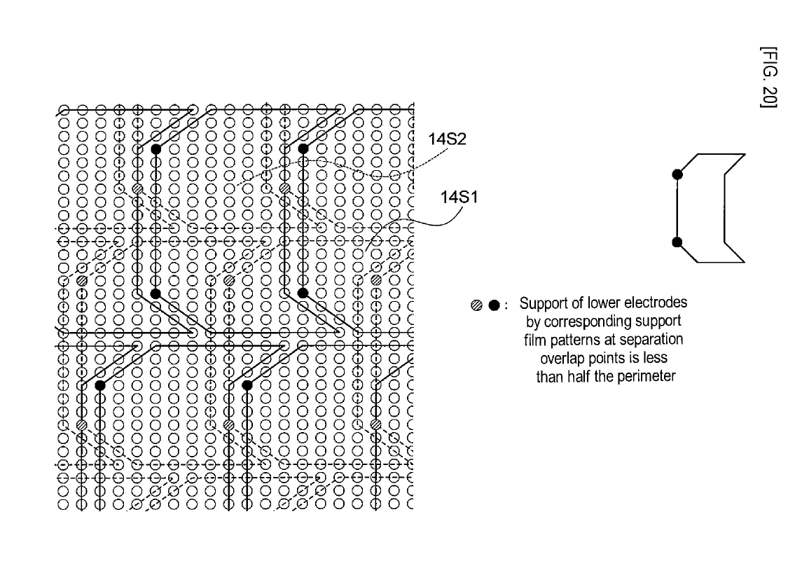

FIG. 18A shows a magnified plan view of a portion near the lower right corner of a memory mat MM. FIG. 18B is a sectional view at line B-B′ in FIG. 18A. As shown in FIGS. 18A and 18B, the first support film pattern 14S1 on the lower side is separated by separation lines to form a honeycomb-shaped (hexagonal) repeating pattern group (first support film pattern group). The second support film pattern 14S2 on the upper side is also separated by separation lines to form a honeycomb-shaped (hexagonal) repeating pattern group (second support film pattern group). During this process, the lower electrodes (supported at less than half the perimeter of the sidewall) located at the separation overlap points (intersections of separation lines) in the first support film pattern 14S1 form a layout in which the separation overlap points of the second support film pattern 14S2 are offset from the separation overlap points of the first support film pattern 14S1 so that half or more of the perimeter is supported by the second support film pattern 14S2. In terms of the pattern of separation lines comprising the outline pattern, the outline pattern may be said to extend in two or more directions while turning. “While turning” means that the angles of the support film patterns are rounded.

### Example 2

As shown in FIG. 19, the first and second support film patterns form repeating pattern groups (first and second support pattern groups) which combine octagonal patterns 14S1-1 and 14S2-1 with rectangular patterns 14S1-2 and 14S2-2, and form a layout in which the separation overlap points of the first and second support film patterns are mutually offset as in Example 1. In FIG. 19, because no lower electrodes are arranged at the separation overlap points (the vertices of the pattern) of the rectangular patterns 14S1-2 and 14S2-2, there are no places where lower electrodes suspended between the rectangular patterns 14S1-2 and 14S2-2 are supported at less than half the perimeter. With the octagonal patterns 14S1-1 and 14S2-1, however, because there are places supported at less than half the perimeter, a layout is required in which the separation overlap points of the second support film pattern (octagonal pattern 14S2-1) are offset from the separation overlap points of the first support film pattern (octagonal pattern 14S1-1).

### Example 3

As shown in FIG. 20, the first and second support film patterns 14S1 and 14S2 form repeating patterns (first and second support pattern groups) of irregular octagons (irregular polygons) which are concave on one side and convex on the other side. In this case, attention must be paid to the lower electrodes arranged at the vertices on the convex side of the irregular octagon other than the separation overlap points where the separation lines are divided in three (shown schematically on the right side of FIG. 20). Specifically, because places where the angle to the vertice of the lower electrodes at the vertices on the convex side of the irregular octagon is less than 180° are supported at less than half the perimeter, whether these places are supported at less than half the perimeter must be reconfirmed when using a layout in which the separation overlap points of the second support film pattern 14S2 are offset from the separation overlap points of the first support film pattern 14S1.

### Example 4

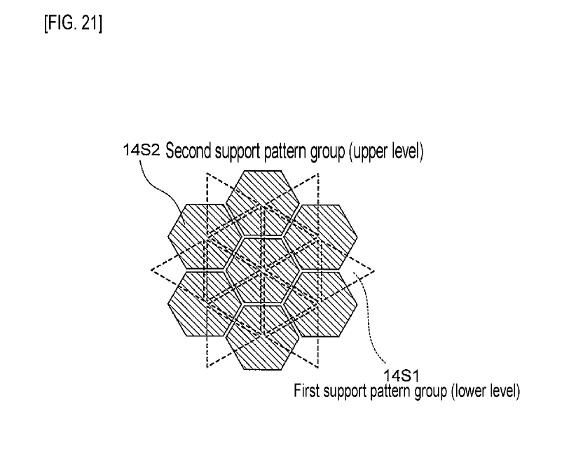

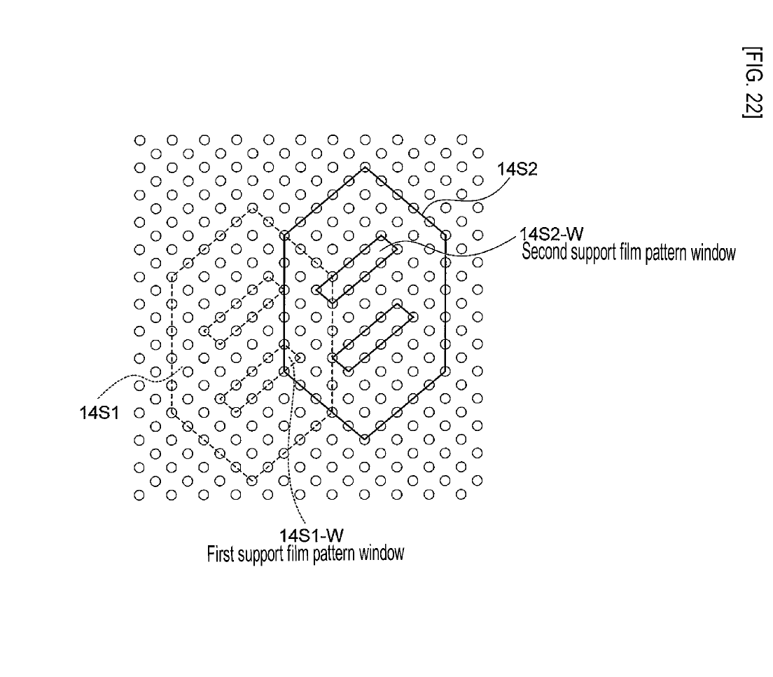

The repeating pattern between the first and second support film patterns 14S1 and 14S2 may be varied as shown in FIG. 21. Specifically, the first support film pattern 14S1 forms a repeating pattern of (equilateral) triangular patterns (first support film pattern group), and the second support film pattern 14S2 forms a repeating pattern of (equilateral) hexagonal patterns (second support film pattern group). Needless to say, the separation overlap points of the second support film pattern 14S2 are offset from the separation overlap points of the first support film pattern 14S1.

### Example 5

As shown in FIG. 22, one or more windows 14S1-W and 14S2-W are made within the first and second support film patterns 14S1 and 14S2 (or within either one of the patterns). Although only one first and one second support film pattern are shown in FIG. 22 for convenience, needless to say, these patterns are formed as repeating patterns. The reason for making windows is the risk of decreasing the routes (which would correspond to the separation lines were there no windows) by which wet etching solution may enter during wet etching of the sacrificial oxide films in FIG. 17 and causing under-etching when the size of the support film patterns is fairly large (several micrometers or greater).

### Effects of the Examples

Instead of only taking a countermeasure to sloping at the edges of a memory map, the examples are designed so that one or the other of two upper and lower support film patterns always supports each lower electrode at half or more of the perimeter of the sidewall. This eliminates the risk of a lower electrode coming off from a support film pattern, sloping, and shorting with an adjacent lower electrode during wet etching of a sacrificial oxide film for exposing the inner and outer walls of the lower electrode, and leads to improved product quality.

The present invention was described above with reference to several examples, but the present invention is not to be taken as limited to these examples. A person skilled in the art may be able to make various modifications without departing from the spirit and scope of the present invention described in the claims.

This application claims priority on the basis of Japanese Patent Application No. 2013-42574 filed on Mar. 5, 2013, the disclosure of which is hereby incorporated by reference.

### EXPLANATION OF REFERENCE NUMBERS

1 Semiconductor substrate
2 Gate electrode groove pattern
3 Element separation region
4 First interlayer insulating film
5 Gate electrode
5a Gate insulating film
5b Sidewall
5c Cap insulating film
6 Bit wiring
7 Second interlayer insulating film
7A Capacitor contact plug
8 Impurity diffusion layer
9 Substrate contact plug
10 Capacitor contact pad
11 Ghird interlayer insulating film
12-1 First sacrificial interlayer film (sacrificial oxide film)
12-2 First sacrificial interlayer film (sacrificial oxide film)
13, LE Lower electrode
13a Protective film
15 Upper electrode
20 Fifth interlayer insulating film
21 Upper wiring layer
22 Surface protective film
30 Capacitor element
205a, 205b, 205c Substrate contact portion
SPT-1, 14S1 First support film pattern
SPT-2, 14S2 Second support film pattern
14S1-1, 14S2-1 Octagonal pattern
14S1-2, 14S2-2 Rectangular pattern
300 Support film pattern
350 Lower electrode

1. A semiconductor device comprising:
a plurality of memory cells provided in a memory mat;
each of the plurality of memory cells has a plurality of capacitors;
each of the capacitors has a cylindrical lower electrode;
a first support film pattern group is provided comprising a plurality of polygonal support film patterns within the memory mat as seen in plan view, each supporting a sidewall of the corresponding lower electrode;
a second support film pattern group is provided comprising a plurality of polygonal support film patterns within the memory mat as seen in plan view, each supporting a sidewall of the corresponding lower electrode; and
the second support film pattern group is formed above the first support film pattern group so that the peripheral vertices of the polygons do not overlap each other as seen in plan view.

2. The semiconductor device according to claim 1, wherein each support film pattern of the first support film pattern group and the second support film pattern group is present in a plurality of shapes joining together as a repeating pattern within that support film pattern group.

3. The semiconductor device according to claim 1, wherein all of the lower electrodes are supported at the sidewalls by any of the support film patterns of the first support film pattern group and any of the support film patterns of the second support film pattern group.

4. The semiconductor device according claim 1, wherein the first support film pattern group supports all of the lower electrodes at the sidewalls midway up, and the second support film pattern group supports the sidewalls of the lower electrodes near the top separately from the first support film pattern group.

5. The semiconductor device according to claim 1, comprising a stopper film for supporting the sidewalls of the lower electrodes in a location at the bottom separately from the first support film pattern group.

6. The semiconductor device according to claim 1, wherein the lower electrodes located at the peripheral vertices of each of the support film patterns of the first support film pattern group form an angle of less than 180 degrees with the peripheral vertices, and are supported at half or more of the perimeter of the sidewalls by any of the support film patterns of the second support film pattern group.

7. The semiconductor device according to claim 1, wherein the lower electrodes located at the peripheral vertices of each of the support film patterns of the second support film pattern group form an angle of less than 180 degrees with the peripheral vertices, and are supported at half or more of the perimeter of the sidewalls by any of the support film patterns of the first support film pattern group.

8. A semiconductor device comprising:
a plurality of memory cells provided in a memory mat;
each of the plurality of memory cells has a plurality of capacitors;
each of the capacitors has a cylindrical lower electrode;
a first support film pattern group is provided having an outline pattern comprising a repeating pattern within the memory mat, and comprising a support film pattern supporting the corresponding lower electrode at a sidewall;
a second support film pattern group is provided having an outline pattern of the same repeating pattern as the first support film pattern group within the memory mat, and comprising a support film pattern located above the first support film pattern group while supporting the corresponding lower electrode at a sidewall; and
the outline pattern comprising the repeating pattern of the first support film pattern group does not match the outline pattern comprising the repeating pattern of the second support film pattern group as seen in plan view, and each outline pattern is an outline pattern extending in two or more directions while turning.

9. The semiconductor device according to claim 8, wherein the outline pattern comprising the repeating pattern of the first support film pattern group splits up the first support film pattern group into a plurality of residual patterns comprising polygons, and the outline pattern comprising the repeating pattern of the second support film pattern group splits up the second support film pattern group into a plurality of residual patterns comprising polygons.

10. The semiconductor device according to claim 8, wherein the shape of each of the plurality of residual patterns comprising polygons formed by splitting up the first support film pattern group and the second support film pattern group is present in a plurality of shapes joining together as a repeating pattern within that support film pattern group.

11. The semiconductor device according to claim 8, wherein all of the lower electrodes are supported at the sidewalls by any of the plurality of residual patterns comprising polygons from splitting up the first support film pattern group, and are supported at the sidewalls by any of the plurality of residual patterns comprising polygons from splitting up the second support film pattern group.

12. The semiconductor device according to claim 8, wherein the first support film pattern group supports the sidewalls of the lower electrodes located midway up, and the second support film pattern group supports the sidewalls of the lower electrodes near the top separately from the first support film pattern group.

13. The semiconductor device according to claim 8, comprising a stopper film for supporting the sidewalls of the lower electrodes in a location at the bottom separately from the first support film pattern group.

14. The semiconductor device according to claim 8, wherein each of the plurality of residual patterns comprising polygons from splitting up the first support film pattern group has a lower electrode not supported around the entire perimeter of the sidewall; and
each of the plurality of residual patterns comprising polygons from splitting up the second support film pattern group has a lower electrode not supported around the entire perimeter of the sidewall.

15. The semiconductor device according to claim 8, wherein each of the plurality of residual patterns comprising polygons from splitting up the first support film pattern group has a lower electrode not supported around the entire perimeter of the sidewall at a region excluding the outer perimeter of the residual pattern.

16. The semiconductor device according to claim 8, wherein each of the plurality of residual patterns comprising polygons from splitting up the second support film pattern group has a lower electrode not supported around the entire perimeter of the sidewall at a region excluding the outer perimeter of the residual pattern.

17. A semiconductor device comprising:
a plurality of memory cells provided in a memory mat;
each of the plurality of memory cells has a plurality of capacitors;
each of the capacitors has a cylindrical lower electrode;
a first support film pattern group is provided divided by separation lines within the memory mat and supporting the sidewalls of the lower electrodes;
a second support film pattern group is provided divided by separation lines within the memory mat, located above the first support film pattern group, and supporting the sidewalls of the lower electrodes; and
the lower electrodes are divided into:
a first group located at a separation overlap point where the separation lines of the first support film pattern group come together, supported at less than half of the perimeter of the sidewall by one support film pattern of the first support pattern group, and supported at half or more of the perimeter of the sidewall by one support film pattern of the second support pattern group;
a second group located at a separation overlap point where the separation lines of the second support film pattern group come together, supported at half or more of the perimeter of the sidewall by one support film pattern of the first support pattern group, and supported at less than half of the perimeter of the sidewall by one support film pattern of the second support pattern group; and
a third group supported at half or more of the perimeter of the sidewall by one support film pattern of the first support pattern group, and supported at half or more of the perimeter of the sidewall by one support film pattern of the second support pattern group.

18. The semiconductor device according to claim 17, wherein each of the support film patterns in the first support film pattern group and the second support film pattern group is present in a plurality of shapes joining together as a repeating pattern within that support film pattern group.

19. The semiconductor device according to claim 17, wherein the first support film pattern group has a lower electrode not supported around the entire perimeter of the sidewall at a region excluding the relevant separation line.

20. The semiconductor device according to claim 17, wherein the second support film pattern group has a lower electrode not supported around the entire perimeter of the sidewall at a region excluding the relevant separation line.
